(19) United States
(12) Patent Application Publication
(10) Pub. No.: US 2005/0236684 A1
(43) Pub. Date: Oct. 27, 2005

(54) Image sensor packaging structure and method

(75) Inventors: Shou-Lung Chen, Yangnei Township (TW); Fang-Jun Leu, Hsinchu City (TW); Shan-Pu Yu, Taoyeng (TW)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: Taiwan Semiconductor Manufacturing Co., Ltd.

(21) Appl. No.: 10/833,713

(22) Filed: Apr. 27, 2004

(51) Int. Cl. H01L 21/00; H01L 31/0203

(52) U.S. Cl. 257/433; 438/64; 257/778; 438/108

(57) ABSTRACT

A new and improved image sensor packaging structure and method. The image sensor packaging structure includes a glass substrate. A bond pad film, on which is provided multiple, interior flip-chip bond pads and exterior BGA (ball grid array) bond pads, is provided on the glass substrate. An inverted image sensor chip is bonded to the flip-chip bond pads on the glass substrate. The light-receiving face of the chip faces the glass substrate typically through a window provided in the bond pad film. Solder bumps are provided on the BGA bond pads on the bond pad film, and bond pads on a PCB (printed circuit board) are bonded to the respective solder bumps.

### FIELD OF THE INVENTION

The present invention relates to flip chip packaging of semiconductor integrated circuits. More particularly, the present invention relates to a flip-chip packaging structure and method which reduces space particularly in the packaging of image sensors.

### BACKGROUND OF THE INVENTION

One of the last processes in the production of semiconductor integrated circuits (IC) is multi-leveled packaging, which includes expanding the electrode pitch of the IC chips containing the circuits for subsequent levels of packaging; protecting the chip from package internal and external stress; providing proper thermal paths for channeling heat dissipated by the chip; and forming electronic interconnections. The manner in which the IC chips are packaged dictates the overall cost, performance, and reliability of the packaged chips, as well as of the system in which the package is applied.

Package types for IC chips can be broadly classified into two groups: hermetic packages and non-hermetic packages. A chip packaged in a hermetic package is isolated from the ambient environment by a vacuum-tight or special atmosphere enclosure. The package is typically ceramic and is utilized in high-performance applications. A chip packaged in a non-hermetic package, on the other hand, is not completely isolated from the ambient environment Of course, a hermetic package's manufacturing cost is higher than a non-hermetic package's, the hermetic package still have to be used for the special application, such like image sensor or pressure sensor. Recent advances in hermetic package used by plastic, however, has expanded their application and performance capability. Plastic packages are cost-effective due to the fact that the production process is typically facilitated by automated batch-handling.

A recent development in the packaging of IC chips is the ball grid array (BGA) package, which may be utilized with either ceramic packages or plastic packages and involves different types of internal package structures. The BGA package uses multiple solder balls or bumps for electrical, mechanical and thermal interconnection of IC chips to other microelectronic devices. The solder bumps serve to both secure the IC chip to a circuit board and electrically interconnect the chip circuitry to a conductor pattern formed on the circuit board. The BGA technique is included under a broader connection technology known as “Controlled Collapse Chip Connection-C4” or “flip-chip” technology.

Flip chip technology can be used in conjunction with a variety of circuit board types, including ceramic substrates, printed wiring boards, flexible circuits, and silicon substrates. The solder bumps are typically located at the area array of the flip chip on electrically conductive bond pads that are electrically interconnected with the circuitry on the flip chip. Because of the numerous functions typically performed by the microcircuitry of a flip chip, a relatively large number of solder bumps are often required. The size of a flip chip is typically on the order of about thirteen millimeters per side, resulting in crowding of the solder bumps along the perimeter of the flip chip. Consequently, flip chip conductor patterns are typically composed of numerous individual conductors that are often spaced apart about 0.1 millimeter or less.

A section of a typical conventional flip chip 26 is shown schematically in FIG. 1 and includes a solder bump 10 which is soldered directly to the continuous upper surface of a bump pad 14, typically rectangular in configuration, as shown in FIG. 1A, and partially covered by a passivation layer 12 which may be SiN or SiO₂, for example. A circular pad opening 13 in the passivation layer 12 exposes the bump pad 14, through which pad opening 13 the solder bump 10 extends. The bump pad 14 is surrounded by a dielectric layer 15 such as an oxide in the chip 26.

As further shown in FIG. 1, the bump pad 14 is provided in electrical contact with an upper conductive layer 16, which is separated from an underlying conductive layer 22 by an insulative layer 18. The conductive layers 16, 22 are disposed in electrical contact with each other through conductive vias 20 that extend through the insulative layers 18. The various insulative layers 18 and conductive layers 22 are sequentially deposited on a silicon chip substrate 24 throughout semiconductor fabrication, in conventional fashion.

After the solder bumps 10 are formed on the flip chip 26, the chip 26 is inverted (thus the term, “flip chip”) and the solder bumps 10 are bonded to electrical terminals in a substrate 28 such as a printed circuit board (PCB). As shown in FIG. 1B, the solder bumps 10 are typically provided on the flip chip 26 in a series of rows and columns. Frequently, an empty space 11 is left between adjacent solder bumps 10 in the rows and columns on the flip chip 26 due to the configuration of integrated circuits fabricated on the chip substrate 24 or other considerations.

After the solder bumps 10 are bonded to the PCB substrate 28, the flip chip 26 is subjected to a variety of tests such as, for example, bump shear tests and die shear tests, in which shear stress is applied to the flip chip 26 to determine the mechanical integrity of the electrical connections between the flip chip 26 and the bonded PCB substrate 28. The flip chip 26 may also be subjected to temperature tests, in which the flip chip 26 is subjected to temperatures of up to typically about 150 degrees C. However, leadless chip carrier packaging is commonly used to package an image sensor such as a CCD (Charge Coupled Device) or or CMOS (Complementary Metal Oxide Semiconductor) image sensor, for example.

A charge coupled device (CCD) image sensor is an electronic device that is capable of transforming a light pattern or image into an electric charge pattern or electronic image. The CCD includes several photosensitive elements that have the capacity to collect, store and transport electrical charge from one photosensitive element to another. The photosensitive properties of silicon make silicon the material of choice in the design of image sensors. Each photosensitive element represents a picture element, or pixel. With semiconductor technologies and design rules, structures are made that form lines, or matrices, of pixels. One or more output amplifiers at the edge of the chip collect the signals from the CCD. An electronic image can be obtained by applying a series of pulses that transfer the charge of one pixel after another to the output amplifier, line after line. The output amplifier converts the charge into a voltage. External electronics transform the output signal into a form suitable for monitors or frame grabbers.

CMOS (complementary metal oxide semiconductor) image sensors operate at a lower voltage than CCD image sensors, reducing power consumption for portable applications. Each CMOS active pixel sensor cell has its own buffer amplifier and can be addressed and read individually. A commonly used cell has four transistors and a photo-sensing element. The cell has a transfer gate separating the photo sensor from a capacitive “floating diffusion”, a reset gate between the floating diffusion and power supply, a source-follower transistor to buffer the floating diffusion from readout-line capacitance, and a row-select gate to connect the cell to the readout line. All pixels on a column connect to a common sense amplifier.

In addition to their lower power consumption when compared with CCDs, CMOS image sensors are generally of a much simpler design, often having a crystal and decoupling. For this reason, they are easier to design with, generally smaller, and require less support circuitry than CCD image sensors.

A conventional leadless chip carrier package 30 is shown in FIG. 1C. The package 30 is commonly used to package a CCD or CMOS image sensor IC chip and includes a layer of transparent cover glass 32 provided on a support layer 35. An anti-reflective coat 34 is provided between the cover glass 32 and the support layer 35. A multi-layered substrate 36 includes a castellation 42 in which is provided the image sensor die 38. Top leads 40 extend from the die 38 and are disposed in electrical contact with bottom leads 44 that wrap around the sides and bottom of the substrate 36. The transparent cover glass 32 facilitates the transmission of light to the image sensor die 38.

The leadless chip carrier package 30 has a thickness 46 of typically about 2 mm. One of the limitations inherent in using the leadless chip carrier package 30 to package image sensors is the relatively large space consumed by the package 30. This contributes in many cases to the excessive size of the image sensor device. Accordingly, a new and improved packaging structure and method is needed for the packaging of an image sensor.

An object of the present invention is to provide a novel packaging structure for an image sensor.

Another object of the present invention is to provide a novel image sensor packaging structure which is characterized by economy of space.

Still another object of the present invention is to provide a novel BGA (ball grid array) image sensor packaging structure.

Still another object of the present invention is to provide a novel packaging method for the packaging of image sensors.

Another object of the present invention is to provide a novel packaging structure and method which is suitable for the packaging of CCD or CMOS image sensors.

Yet another object of the present invention is to provide a BGA method for the packaging of image sensors.

A still further object of the present invention is to provide an image sensor packaging structure which is characterized by significantly reduced thickness.

### SUMMARY OF THE INVENTION

The present invention is generally directed to a new and improved image sensor packaging structure. The image sensor packaging structure includes a glass substrate. A bond pad film, on which is provided multiple, interior flip-chip bond pads and exterior BGA (ball grid array) bond pads, is provided on the glass substrate. An inverted image sensor chip is bonded to the flip-chip bond pads on the glass substrate, with the image sensor chip facing the glass substrate through a window provided in the bond pad film. Solder bumps (Actually the connecting solder from chip to substrate is call “bump”, and the connecting solder from substrate to mother board is call “ball”) are provided on the BGA bond pads on the bond pad film, and bond pads on a PCB (printed circuit board) are bonded to the respective solder balls.

The image sensor packaging structure of the present invention is characterized by high space efficiency as compared to conventional, leadless chip carrier packages typically used in the packaging of image sensors. The entire thickness of the image sensor packaging structure of the present invention is typically about 800˜1400 _m, as compared to a total thickness of typically about 2 mm for a leadless chip carrier package. Consequently, the image sensor device can be constructed in much smaller sizes than is possible using conventional packaging structures for CCD or CMOS image sensors.

The present invention is further directed to a method for packgaging an image sensor. The method includes providing a glass substrate; providing a bond pad film on which is provided multiple, interior flip-chip bond pads and exterior BGA (ball grid array) bond pads; providing the bond pad film on the glass substrate; providing solder bumps on the respective image sensor chip bond pads; bonding an inverted image sensor chip to flip-chip bond pads on the film; providing BGA solder balls on the BGA bond pads; and bonding a PCB (printed circuit board) to the BGA solder balls.

### BRIEF DESCRIPTION OF THE DRAWINGS

The invention will now be described, by way of example, with reference to the accompanying drawings, in which:

FIG. 1 is a cross-sectional view illustrating a typical conventional solder bump and bump pad construction of a semiconductor flip chip;

FIG. 1A is a top schematic view illustrating a typical conventional solder bump and bump pad construction of a semiconductor flip chip;

FIG. 1B is a top view of a section of a conventional flip chip, with multiple solder bumps provided in rows on the chip;

FIG. 1C is a cross-sectional view of a typical conventional leadless chip carrier package commonly used in the packaging of an image sensor;

FIG. 2A is an exploded, perspective view of a bond pad film on which is provided multiple, interior flip-chip bond pads and exterior BGA bond pads, illustrating mounting of the bond pad tape on a glass substrate;

FIG. 2B is a perspective view of the bond pad film provided on the glass substrate;

FIG. 2C is an end view of an image sensor packaging structure of the present invention, with an inverted image sensor chip bonded to flip-chip bond pads on the bond pad film;

FIG. 2D is an end view of an image sensor packaging structure of the present invention, with underfill material surrounding the flip-chip bond pads and the solder bumps bonding the flip-chip bond pads to the image sensor chip;

FIG. 2E is an end view of an image sensor packaging structure of the present invention, with a PCB (printed circuit board) bonded to the image sensor packaging structure; and

FIG. 3 is a flow diagram illustrating a typical sequence of packaging steps according to the method of the present invention.

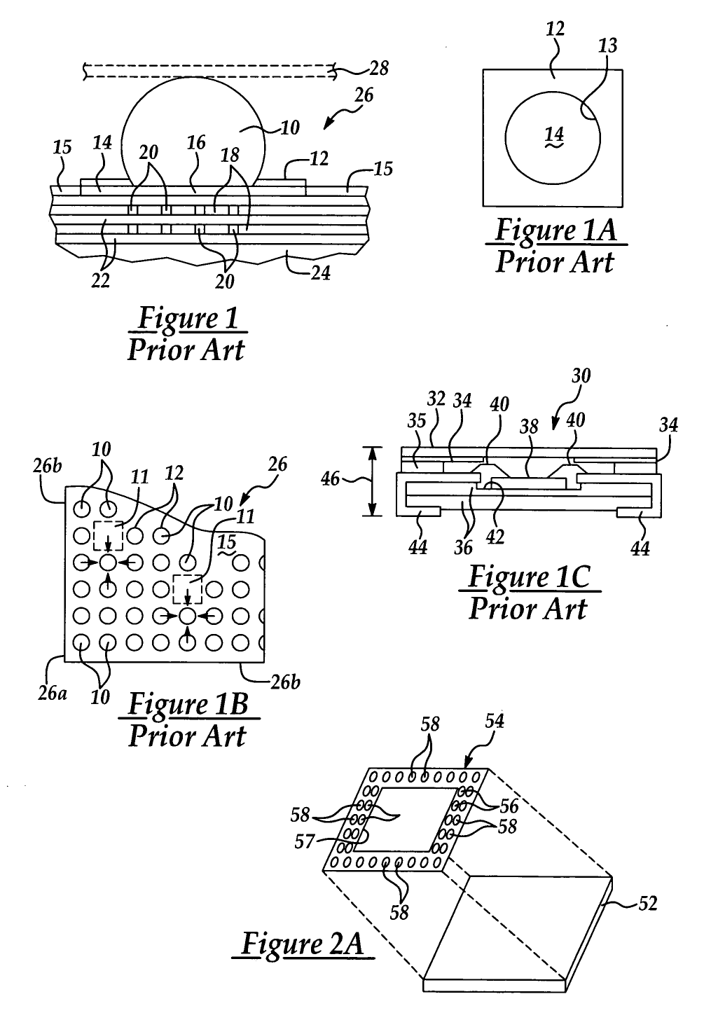

### DETAILED DESCRIPTION OF THE INVENTION

The present invention contemplates a structure and method for the packaging of an image sensor IC (integrated circuit) chip. The structure is a flip-chip BGA (ball grid array) packaging structure which is characterized by a high space efficiency as compared to conventional packaging structures for image sensors. Consequently, the image sensor device can be constructed in much smaller sizes than is possible using conventional packaging structures. The packaging structure may be adapted to either CCD image sensors or CMOS image sensors.

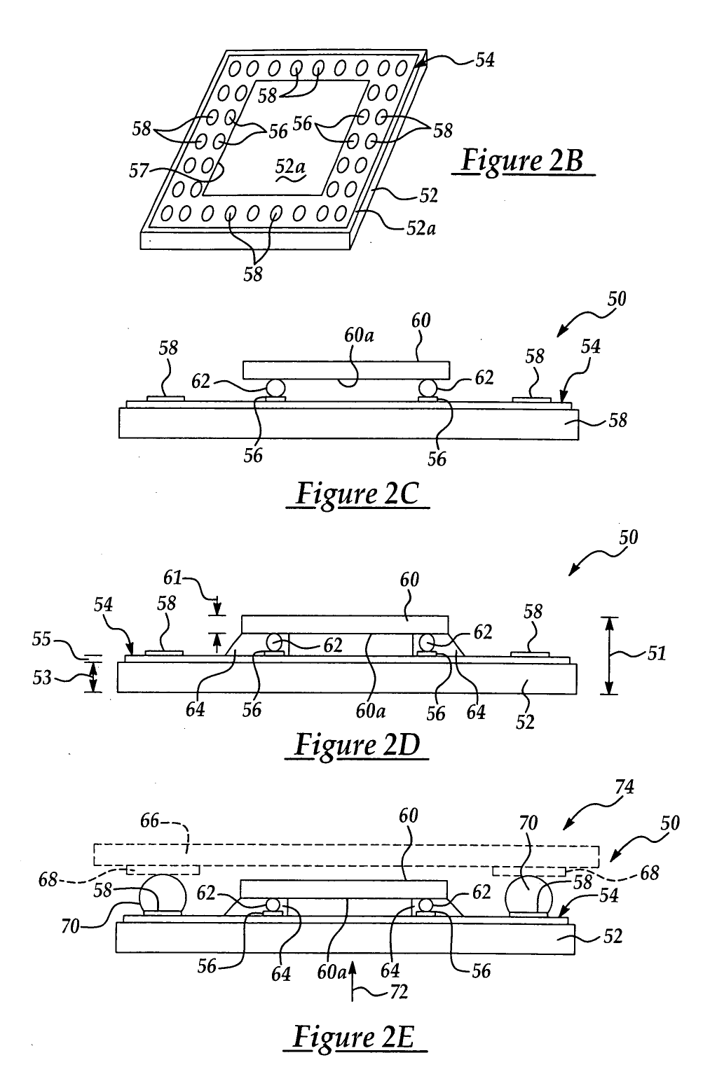

Referring initially to FIGS. 2D and 2E, a complete image sensor packaging structure 50 according to the present invention is shown. The packaging structure 50 includes a glass substrate 52, on which is provided a bond pad film 54 which is typically PI (polyimide) film, for example. As shown in FIG. 2D, the glass substrate 52 has a substrate thickness 53 of from typically about 400 μm to typically about 600 μm, whereas the bond pad film 54 has a film thickness 55 of typically about 100 μm. Multiple, interior flip-chip bond pads 56 and exterior BGA (ball grid array) bond pads 58 are provided on the upper surface of the bond pad film 54. Each interior bond pad 56 is electrically patterned to an exterior bond pad 58, if necessary (I mean there may be multi-I/Os on chip to combine as one or less than initial electrical path to BGA bond pad). An interior solder bump 62, which may be tin, lead or a mixture of tin and lead, for example, is bonded to each of the interior bond pads 56. An exterior solder ball 70, typically having the same composition as that of the interior solder bumps 62, is bonded to each of the exterior bond pads 58.

An inverted CCD (charge-coupled device) or CMOS (complementary metal oxide semiconductor) image sensor IC chip 60 is bonded to the interior solder bumps 62. As shown in FIG. 2D, the IC chip 60 has a chip thickness 61 of typically about 250 μm. The IC chip 60 has a light-receiving face 60a which faces the glass substrate 52 through a film window 57 (FIG. 2B), provided in the center of the bond pad film 54. Accordingly, the image sensor IC chip 60 is positioned for receiving a light image 72 through the glass substrate 52 and film window 57. A PCB (printed circuit board) substrate 66 is bonded to the exterior solder balls 70 through respective bond pads 68 provided on the PCB substrate 66. The PCB substrate 66 includes the external electronics necessary to transform the light image 72 received by the image sensor IC chip 60, into an output signal suitable for a monitor or frame grabber, for example. An underfill material 64 may be provided between the bond pad film 54 and IC chip 60, and covers the interior bond pads 56 and solder bumps 62.

Referring next to FIGS. 2A-2E, and initially to FIG. 2A, the bond pad film 54 typically has a rectangular configuration and may be a PI (polyimide) tape, for example. The film window 57 typically has a rectangular configuration and extends through the center of the bond pad film 54. The multiple exterior bond pads 58 are typically arranged in rows along all four exterior edges of the bond pad film 54. The multiple interior bond pads 56 are typically arranged in rows which extend parallel to the rows of exterior bond pads 58, along opposite edges of the film window 57. The bond pad film 54 is provided on the upper surface of the glass substrate 52. As shown in FIG. 2B, an antireflective IR coating or lens 52a is typically provided on the upper surface of the glass substrate 52.

As shown in FIG. 2C, after the bond pad film 54 is provided on the glass substrate 52, an interior solder bump 62, which may be tin/lead, for example, is formed on each interior bond pad 56. The image sensor IC chip 60 is then inverted and bonded into electrical contact with the respective interior solder bumps 62. Accordingly, the light receiving face 60a of the IC chip 60 faces the upper surface 52a of the glass substrate 52, through the film window 57.

As shown in FIG. 2D, an underfill material 64 is deposited between the bond pad film 54 and the IC chip 60 and covers each interior solder bump 62. The underfill material 64 protects the interior bond pads 56 and interior solder bumps 62 from dust, moisture and other contaminants, as well as enhances the electrical interconnection reliability between the interior bond pads 56 and the IC chip 60. The underfill material 64 may be any suitable material including epoxy with fine scale fillers for enhancing the thermal dissipation.

As shown in FIG. 2E, after the underfill material 64 is deposited between the bond pad film 54 and the IC chip 60, the exterior solder balls 70 are formed on the respective exterior bond pads 58. The multiple bond pads 68 on the PCB substrate 66 are then bonded to the respective exterior solder balls 70 to complete the image sensor device 74.

Referring again to FIG. 2D, it will be appreciated by those skilled in the art that the image sensor packaging structure 50 of the present invention has an overall thickness 51 of from typically about 800 μm to typically about 1,400 μm. This is much less than the overall thickness of typically about 2 mm for a conventional image sensor packaging structure. Consequently, the image sensor device 74 can be constructed in much smaller sizes than is possible using conventional packaging structures for CCD or CMOS image sensors.

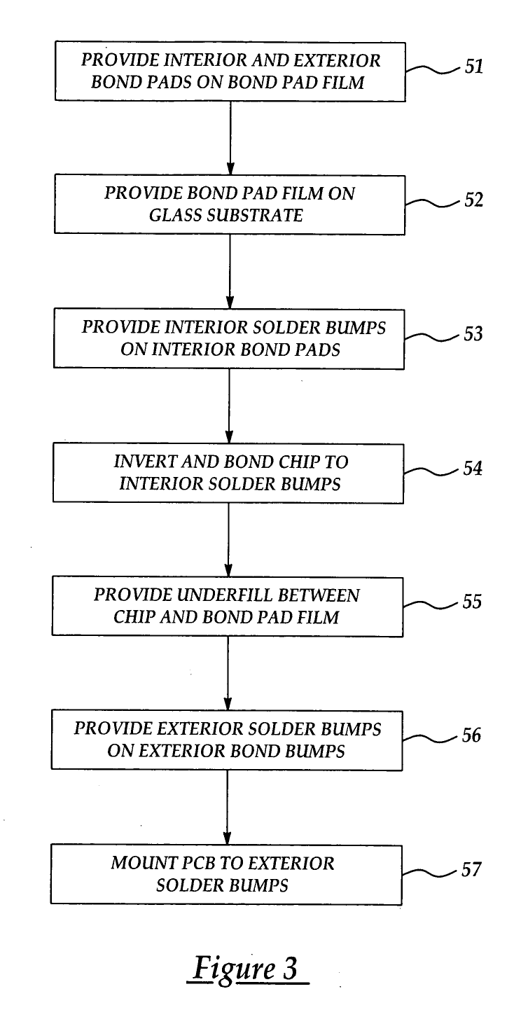

A flow diagram which summarizes typical process steps in the fabrication of the image sensor packaging structure is shown in FIG. 3. In process step S1, interior and exterior bond pads are provided on a bond pad film. In process step S2, the bond pad film is provided on a glass substrate. In process step S3, interior solder bumps are provided on the interior bond pads of the bond pad film. In process step S4, the image sensor IC chip is inverted and bonded to the interior solder bumps. In process step S5, underfill material is provided between the IC chip and the bond pad film to protect the interior bond pads and solder bumps from dust, moisture and other contaminants. In process step S6, exterior solder balls are provided on the respective exterior bond pads of the bond pad film. In process step S7, the PCB is mounted to the exterior solder balls.

While the preferred embodiments of the invention have been described above, it will be recognized and understood that various modifications can be made in the invention and the appended claims are intended to cover all such modifications which may fall within the spirit and scope of the invention.

1. An image sensor packaging structure, comprising:
a generally transparent substrate;
a first set of electrical contacts carried by said substrate;
an image sensor integrated circuit chip provided in electrical communication with said first set of electrical contacts; and
a second set of electrical contacts carried by said substrate in electrical communication with said first set of electrical contacts.

2. The structure of claim 1 wherein said first set of electrical contacts comprises a plurality of interior bond pads and further comprising a plurality of interior solder bumps connecting said image sensor integrated circuit chip to said plurality of interior bond pads, respectively.

3. The structure of claim 1 wherein said second set of electrical contacts comprises a plurality of exterior bond pads and further comprising a plurality of exterior solder bumps carried by said plurality of exterior bond pads, respectively.

4. The structure of claim 3 wherein said first set of electrical contacts comprises a plurality of interior bond pads and further comprising a plurality of interior solder bumps connecting said image sensor integrated circuit chip to said plurality of interior bond pads, respectively.

5. The structure of claim 2 further comprising an underfill material substantially covering said plurality of interior bond pads and said plurality of solder bumps.

6. The structure of claim 5 wherein said second set of electrical contacts comprises a plurality of exterior bond pads and further comprising a plurality of exterior solder bumps carried by said plurality of exterior bond pads, respectively.

7. The structure of claim 1 further comprising a film carried by said substrate and wherein said first set of electrical contacts and said second set of electrical contacts are carried by said film.

8. The structure of claim 7 wherein said first set of electrical contacts comprises a plurality of interior bond pads and further comprising a plurality of interior solder bumps connecting said image sensor integrated circuit chip to said plurality of interior bond pads, respectively.

9. The structure of claim 7 wherein said second set of electrical contacts comprises a plurality of exterior bond pads and further comprising a plurality of exterior solder bumps carried by said plurality of exterior bond pads, respectively.

10. The structure of claim 9 wherein said first set of electrical contacts comprises a plurality of interior bond pads and further comprising a plurality of interior solder bumps connecting said image sensor integrated circuit chip to said plurality of interior bond pads, respectively.

11. The structure of claim 8 further comprising an underfill material substantially covering said plurality of interior bond pads and said plurality of solder bumps.

12. The structure of claim 11 wherein said second set of electrical contacts comprises a plurality of exterior bond pads and further comprising a plurality of exterior solder bumps carried by said plurality of exterior bond pads, respectively.

13. An image sensor packaging structure, comprising:
a generally transparent substrate;
a generally rectangular film having a central window carried by said substrate;
a first set of electrical contacts carried by said film;
an image sensor integrated circuit chip provided in electrical communication with said first set of electrical contacts and facing said substrate through said window; and
a second set of electrical contacts carried by said film in electrical communication with said first set of electrical contacts.

14. The structure of claim 13 wherein said first set of electrical contacts comprises a plurality of interior bond pads and further comprising a plurality of interior solder bumps connecting said image sensor integrated circuit chip to said plurality of interior bond pads, respectively.

15. The structure of claim 14 wherein said second set of electrical contacts comprises a plurality of exterior bond pads and further comprising a plurality of exterior solder balls carried by said plurality of exterior bond pads, respectively.

16. The structure of claim 15 further comprising an underfill material substantially covering said plurality of interior bond pads and said plurality of interior solder bumps only.

17. A method of packaging an image sensor, comprising the steps of:
providing a generally transparent substrate;
providing a first set of electrical contacts on said substrate;
providing a second set of electrical contacts on said substrate in electrical communication with said first set of electrical contacts; and
providing an image sensor integrated circuit chip in electrical communication with said first set of electrical contacts.

18. The method of claim 17 wherein said providing a first set of electrical contacts on said substrate comprises providing a bond pad film, providing a plurality of interior bond pads on said bond pad film (as aforementioned, bumping process is provided on IC, not on substrate), respectively.

19. The method of claim 18 wherein said providing a second set of electrical contacts on said substrate comprises providing a plurality of exterior bond pads on said bond pad film and providing a plurality of exterior solder balls on said plurality of exterior bond pads, respectively.

20. The method of claim 18 further comprising the step of providing an underfill material between said substrate and said image sensor integrated circuit chip and substantially covering said plurality of interior bond pads and said plurality of interior solder bumps.
